(19) United States
(12) Patent Application Publication
(10) Pub. No.: US 2018/0030614 A1
(43) Pub. Date: Feb. 1, 2018

(54) FEED SYSTEM FOR CRYSTAL GROWING SYSTEMS

(71) Applicant: SUNEDISON SEMICONDUCTOR LIMITED, Singapore (SG)

(72) Inventors: Stephan Haringer, Kastelbell-Tschars (IT); Gianni Dell'Amico, Merano (IT); Marco D'Angella, Merano (IT); Renzo Odorizzi, Gargazone (IT); Maria Porrini, Merano (IT); Enrico Rigon, Merano (IT); Valentino Moser, Naturno (IT)

(21) Appl. No.: 15/549,919

(22) PCT Filed: Feb. 12, 2015
(86) PCT No.: PCT/SG2015/000044

§ 371 Date: Aug. 9, 2017

(51) Int. Cl. C30B 15/00; C30B 29/06

(52) U.S. Cl. CPC C30B 15/00; C30B 29/06

(57) ABSTRACT

A system for growing a crystal ingot from a melt includes a housing and a feed system. The housing defines a growth chamber and an ingot removal chamber positioned above the growth chamber. The feed system includes an enclosure, a feed material reservoir positioned within the enclosure, and a feed channel including an intake end and an outlet end. The intake end is configured to receive feed material from the feed material reservoir. The housing has an opening in communication with the removal chamber and a connector proximate the opening, and the enclosure has an opening and a connector configured to mate with the housing connector. The feed channel is moveable between a retracted position and an extended position in which the feed channel extends through the opening in the housing and the outlet end is positioned within the removal chamber.

### FIELD

The field of the disclosure relates generally to systems for growing single crystal ingots from a melt of semiconductor or solar material, and, more particularly, to feed systems for use with such systems.

### BACKGROUND

In the production of silicon crystals grown by the Czochralski (CZ) method, polycrystalline silicon is first melted within a crucible, such as a quartz crucible, of a crystal growing system to form a silicon melt. A pulling mechanism then lowers a seed crystal into contact with the melt and then slowly raises the seed crystal out of the melt. As the seed crystal is raised from the melt, silicon atoms from the melt align themselves with and attach to the seed crystal to form a single crystal ingot. In a batch CZ method, the silicon melt is depleted as the ingot is grown. When the melt reaches a certain level, or the ingot reaches a desired length, the ingot is separated from the melt and removed from the crystal growing system.

In some batch CZ methods, the crystal growing system is cooled, cleaned, and degassed, and the crucible is recharged with polycrystalline silicon in between each successive ingot growth cycle. Performing each of these steps in between each successive ingot growth cycle results in significant down time of the crystal growing system.

In other batch CZ methods, silicon feed material is fed into a crucible through an access port of the crystal growing system to enable the crucible to be recharged without cooling the crystal growing system between each successive ingot growth cycle. However, the size of access ports on typical crystal growing systems limits the size of silicon feed material that may be fed through the access ports, and generally requires smaller, more expensive silicon feed material to be used. Modifying at least some conventional crystal growing systems to receive larger, less expensive chunk polycrystalline silicon would require modification of the hot zone configuration of the crystal pulling device and, consequently, would affect the growth environment and conditions (e.g., thermal conditions) within the crystal growing system during growth of a crystal ingot. Moreover, where the crystal growing system has a liquid-cooled housing, modifying the size of the access port would require significant modification.

Accordingly, a need exists for a feed system that enables large chunk feed material to be fed into a crystal growing system without significant modification of the hot zone configuration of the crystal growing system.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a system for growing a crystal ingot from a melt includes a housing and a feed system. The housing defines a growth chamber and an ingot removal chamber positioned above the growth chamber. The feed system includes an enclosure, a feed material reservoir positioned within the enclosure, and a feed channel including an intake end and an outlet end. The intake end is configured to receive feed material from the feed material reservoir. The housing has an opening in communication with the removal chamber and a connector proximate the opening, and the enclosure has an opening and a connector configured to mate with the housing connector. The feed channel is moveable between a retracted position and an extended position in which the feed channel extends through the opening in the housing and the outlet end is positioned within the removal chamber.

In another aspect, a feed system for use with a crystal growing system includes a housing defining a growth chamber and a removal chamber positioned above the growth chamber. The feed system includes an enclosure, a feed material reservoir, and a feed channel. The enclosure defines an interior volume and an opening providing communication with the interior volume. The enclosure includes a connector that is proximate the opening and configured to connect the enclosure to the housing. The feed material reservoir is positioned within the interior volume of the enclosure. The feed channel includes an intake end and an outlet end. The intake end is configured to receive feed material from the feed material reservoir. The feed channel is moveable between a retracted position and an extended position in which the feed channel extends through the opening in the enclosure and into the removal chamber of the crystal growing system.

In yet another aspect, a method of retrofitting a crystal growing system with a feed system is provided. The feed system includes a feed channel moveable between a retracted position and an extended position. The crystal growing system includes a housing defining a growth chamber and an ingot removal chamber positioned above the growth chamber. The method includes forming a feed port in the housing, the feed port providing communication with the removal chamber of the crystal growing system, and connecting the feed system to the housing such that, when the feed channel is in the extended position, the feed channel extends through the feed port and into the removal′ chamber.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is cross-section of a crystal growing system including an example feed system;

FIG. 2 is a perspective view of the feed system of FIG. 1;

FIG. 3 is a cross-section of the feed system of FIG. 1;

FIG. 4 is a cross-section of a feed channel of the feed system of FIG. 1;

FIG. 5 is a cross-section of a crystal growing system including another embodiment of a feed system mounted on a carriage; and

FIG. 6 is a flow chart of an example method of retrofitting a crystal growing system with a feed system.

Corresponding reference characters indicate corresponding parts throughout the several views of the drawings.

### DETAILED DESCRIPTION

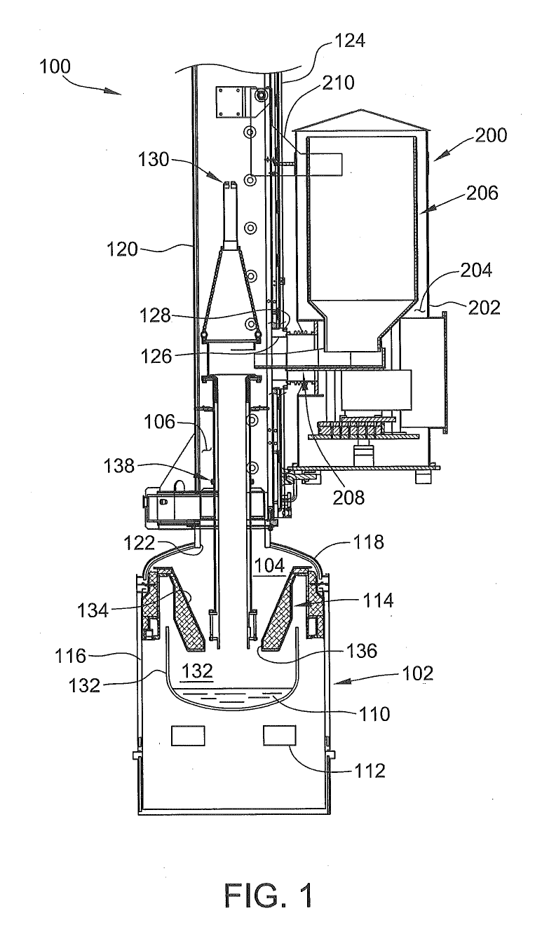

Referring to FIG. 1, a crystal growing system is shown schematically and is indicated generally at 100. The crystal growing system 100 is used to produce single crystal ingots by the Czochralski method. As discussed herein, the system is described in relation to a batch or recharge Czochralski method of producing single crystal ingots.

The illustrated crystal growing system 100 generally includes a housing 102 defining a growth chamber 104 and an ingot removal chamber 106 connected to and positioned above the growth chamber 104. A crucible 108 containing a melt 110 of semiconductor or solar-grade material (e.g., silicon) is positioned within the growth chamber 104, and one or more heating elements 112 are positioned proximate the crucible 108 for supplying thermal energy to the system 100. A heat shield 114 is positioned within the growth chamber 104 adjacent the crucible 108, and is configured to shield a crystal ingot (not shown) being grown from the melt 110 from radiant heat to allow the ingot to solidify. The crystal growing system 100 also includes a feed system 200 removably connected to the housing 102 along the ingot removal chamber 106, and configured to feed feedstock material, such as chunk polycrystalline silicon (poly-silicon), into the crucible 108.

The housing 102 includes a lower portion 116, an upper dome 118 connected to the lower portion 116, and an elongate tubular portion 120 extending generally upward from the upper dome 118. In the illustrated embodiment, the growth chamber 104 is defined by the lower portion 116 and the upper dome 118, and the ingot removal chamber 106 is generally defined by the elongate tubular portion 120. The upper dome 118 includes a central annular opening 122 providing communication between the growth chamber 104 and the removal chamber 106. The tubular portion 120 includes an access door 124 that provides access to the ingot removal chamber 106.

The housing 102 includes a feed port 126 (broadly, an opening) located along the tubular portion 120 of the housing 102 through which feedstock material from the feed system 200 may be introduced into the removal chamber 106. In the illustrated embodiment, the feed port 126 is defined along the access door 124, although the feed port 126 may be located along any suitable location of the housing 102 that enables the feed system 200 to function as described herein. The housing 102 also includes a connector 128 circumscribing the feed port 126. The connector 128 is configured to sealingly engage a component of the feed system 200 to facilitate maintaining a controlled, sealed environment within the removal chamber 106 and the growth chamber 104. Suitable connectors include, but are not limited to, vacuum flanges. In some embodiments, the housing 102 may also include a feed port door or seal (not shown) configured to seal the feed port 126 when the feed system 200 is not connected to the housing 102.

The housing 102 may be made of stainless steel or other suitable materials. In some embodiments, one or more of the lower portion 116, the upper dome 118, and the tubular portion 120 are constructed from water-cooled stainless steel walls.

The crucible 108 is positioned within the growth chamber 104 and beneath the removal chamber 106 such that an ingot grown from the melt 110 can be pulled by a crystal pulling mechanism 130 through the central opening 122 in the upper dome 118 and into the removal chamber 106. The crucible 108 may be supported within the growth chamber 104 by a susceptor (not shown) and a rotatable shaft (not shown) configured to rotate the crucible 108 during growth of a crystal ingot.

The crucible 108 may be constructed from, for example, quartz or any other suitable material that enables the crystal growing system 100 to function as described herein. Further, the crucible 108 may have any suitable size that enables the crystal growing system 100 to function as described herein. In some embodiments, the crucible 108 has a diameter of between about 20 inches and about 32 inches, more suitably between about 20 inches and about 28 inches, and even more suitably between about 20 inches and about 24 inches.

The heat shield 114 is operably connected to the housing 102, and extends from the housing 102 into a cavity 132 defined by the crucible 108. The heat shield 114 separates the melt 110 from an upper portion of the growth chamber 104, and is configured to shield a growing ingot from radiant heat generated by the melt 110 and the heating elements 112 to allow the ingot to solidify. In the example embodiment, the heat shield 114 includes a conical member 134 separating the melt 110 from an upper portion of the growth chamber 104, and a central opening 136 defined therein to allow an ingot to be pulled therethrough. Further, in the example embodiment, the heat shield 114 is free of holes or openings, other than the central opening 136. In other embodiments, the heat shield 114 may have any suitable configuration that enables the system 100 to function as described herein. The heat shield 114 may be constructed from any suitable material that enables the system 100 to function as described herein including, for example and without limitation, graphite, silica-coated graphite, high purity molybdenum, and combinations thereof.

In the embodiment illustrated in FIG. 1, the crystal growing system 100 also includes a guide tube 138 connected to the crystal pulling mechanism 130 and configured to guide feedstock material from the feed system 200 into the crucible 108. In some embodiments, the guide tube 138 is configured to reduce the velocity of feedstock material fed from the feed system 200 through the guide tube 138 to inhibit splashing of the melt 110 and excessive wear of the crucible 108.

During the crystal growing process, an initial charge of semiconductor or solar material is added to the crucible 108, and is heated with the heating elements 112 until melted to form the melt 110. The initial charge of material may be manually fed into the crucible or, as described in more detail herein, fed by the feed system 200. A desired type and amount of dopant may be added to the melt 110 to modify the base resistivity of ingots grown from the melt. A seed crystal (not shown) is lowered by a crystal pulling mechanism 130 into contact with the melt 110, and then slowly raised from the melt 110. As the seed crystal is slowly raised from the melt 110, atoms from the melt 110 align themselves with and attach to the seed crystal to form an ingot. When the growing ingot reaches a desired length and/or when the level of the melt 110 falls below a certain level, the ingot is separated from the melt 110 and pulled into the ingot removal chamber 106. A small portion of the initial melt, also referred to as pot scrap, remains in the crucible 108 following removal of the ingot.

In conventional batch crystal growing systems, once an ingot is grown from an initial charge, the system is cooled to room temperature to enable the system to be charged with additional melt material. Often, thermal cycling of crystal growing systems results in accelerated consumption of consumable components, such as the crucible. For example, quartz crucibles used in crystal growing systems often crack or fracture when the system is cooled following growth of a crystal ingot. Moreover, thermal cycling of crystal growing systems in between each successive ingot growth cycle results in significant down time.

The feed systems described herein are configured to increase the productivity of batch, crystal growing systems by reducing the costs and downtime associated with batch CZ crystal growing processes. For example, the feed systems described herein enable crystal growing systems to be recharged with feedstock material without cooling the system to room temperature. The feed systems described herein thereby enable consumable components, such as quartz crucibles, to be re-used to grow multiple ingots and reduce the down time associated with cooling crystal, growing systems in between ingot growth cycles. Additionally, the feed systems described herein are configured to feed less expensive, large chunk poly-silicon into the crucibles of crystal growing systems, thereby facilitating reducing the costs associated with growing single crystal ingots. The feed systems described herein further facilitate reducing the costs associated with growing single crystal ingots by eliminating the need for every crystal growing system to have a dedicated feeding system. In particular, the feed systems described herein are transportable, and are readily connectable to crystal growing systems to enable one feed system to feed feedstock material into more than one crystal growing system.

Referring still to FIG. 1, the illustrated feed system 200 generally includes an enclosure 202 defining an interior volume 204, a feed material reservoir 206 configured to hold feedstock material therein, and a feed channel 208 configured to guide feedstock material from the feed material reservoir 206 into the crucible 108. In the embodiment illustrated in FIG. 1, the feed system 200 is mounted to the housing 102 by mounting brackets 210.

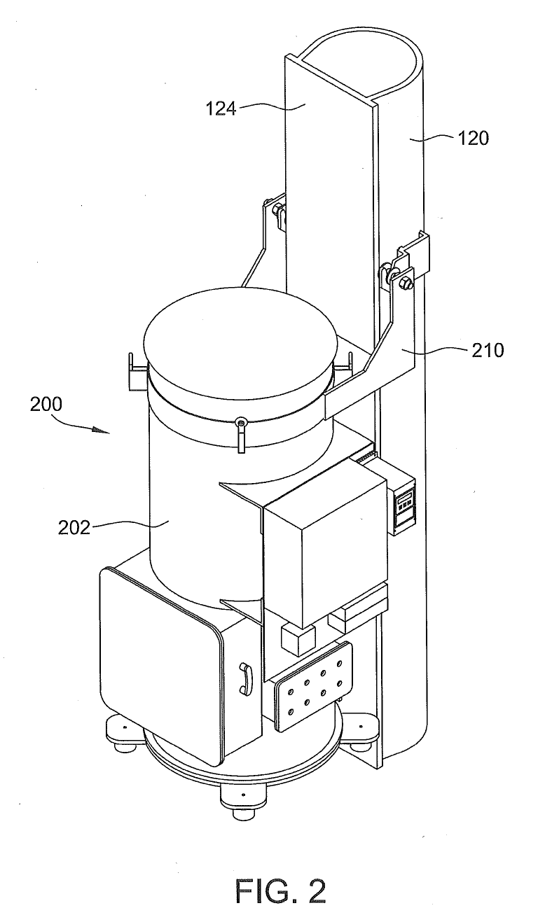

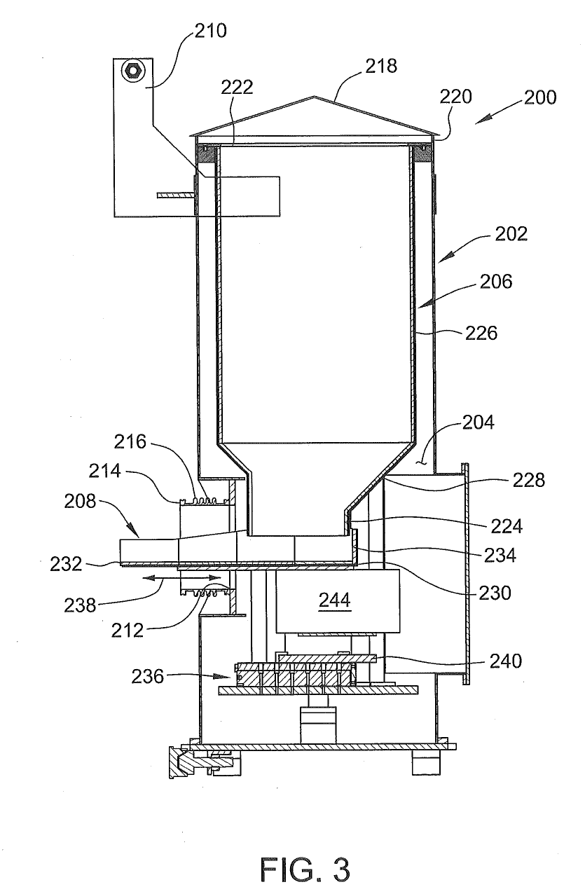

FIG. 2 is a perspective view of the feed system 200 of FIG. 1 connected to the tubular portion 120 of the housing 102, and FIG. 3 is an enlarged view of the feed system 200 of FIG. 1. With additional reference to FIGS. 2 and 3, the enclosure 202 is generally configured to enclose components of the feed system 200, such as the feed material reservoir 206 and the feed channel 208, within a sealed environment. The enclosure 202 may be constructed from any suitable material that enables the feed system 200 to function as described herein including, for example and without limitation, stainless steel.

The enclosure 202 defines an opening 212 sized to receive the feed channel 208 therein. In some embodiments, the opening 212 is sized to permit relatively large chunk poly-silicon to be fed therethrough. In some embodiments, for example, the opening 212 has a diameter of at least about 150 mm, at least about 200 mm, or even at least about 250 mm.

The enclosure 202 includes a connector 214 circumscribing the opening 212, and configured to sealingly engage the connector 128 on the housing 102 to provide a sealed connection between the interior volume 204 of the enclosure 202 and the removal chamber 106. Suitable connectors include, but are not limited to, vacuum flanges.

In the illustrated embodiment, the enclosure connector 214 is operably connected to the enclosure 202 by an expansion joint 216. The expansion joint 216 is configured to expand and retract to enable the connector 214 to move relative to the enclosure 202 and facilitate connecting the connectors 128 and 214. The expansion joint 216 may include any suitable device that enables the feed system 200 to function as described herein including, for example and without limitation, stainless steel bellows.

The enclosure 202 also includes a cover 218 moveable between an open position and a closed position to provide access to the feed material reservoir 206 and enable the feed material reservoir 206 to be refilled with feedstock material. The cover 218 is configured to seal the interior volume 204 of the enclosure 202 when the cover 218 is in the closed position (shown in FIGS. 1-3). In the illustrated embodiment, the cover 218 is disposed at the top 220 of the enclosure 202, although the cover 218 may be positioned at any suitable location along the enclosure 202 that enables the feed system 200 to function as described herein.

The feed material reservoir 206 is positioned within the interior volume 204 of the enclosure 202, and is configured to hold a suitable amount of feedstock material therein. In some embodiments, the feed material reservoir 206 is configured to hold a sufficient amount of feedstock material to enable multiple recharging operations to be carried out without refilling the feed material reservoir 206. In some embodiments, for example, the feed material reservoir 206 is configured to hold at least about 10 kilograms (kg) of feedstock material, more suitably at least about 50 kg of feedstock material, and yet even more suitably, at least about 150 kg of feedstock material.

The feed material reservoir 206 includes an inlet 222 at the top of the feed material reservoir 206, and an outlet 224 positioned at the bottom of the feed material reservoir 206. The outlet 224 of the feed material reservoir 206 is suitably sized and shaped to permit chunk feedstock material, such as chunk poly-silicon, to be fed therethrough and into the feed channel 208. In some embodiments, the outlet 224 is sized and shaped to permit relatively large chunk poly-silicon, such as chunk poly-silicon having a maximum feature size or length of at least about 30 mm, at least about 40 mm, at least about 45 mm, and even up to about 60 mm, to be fed therethrough. The maximum feature size or length of a piece of chunk poly-silicon refers to the largest dimension of the piece of chunk poly-silicon measured along a single direction or axis of the piece of chunk poly-silicon. In some embodiments, for example, the outlet 224 includes an annular opening having a diameter of at least about 100 mm, more suitably at least about 200 mm, and even more suitably, at least about 250 mm. In the embodiment illustrated in FIGS. 1-3, the feed material reservoir 206 includes an annular sidewall 226 and a tapered bottom wall 228 extending from the sidewall 226 to the outlet 224 to facilitate guiding feedstock material towards the outlet 224.

Components of the feed material reservoir 206 may include an inert or non-reactive coating or cover to inhibit contamination of feedstock material. In some embodiments, for example, at least the interior surfaces of the annular sidewall 226, the tapered bottom wall 228, and the outlet 224 are covered with quartz. In other embodiments, one or more of the annular sidewall 226, the tapered bottom wall 228, and the outlet 224 is coated with silicon.

The feed channel 208 includes an intake end 230 positioned proximate the outlet 224 of the feed material reservoir 206, and an outlet end 232 distal from the intake end 230. The feed channel 208 includes a back plate 234 at the intake end 230 to inhibit feedstock material from falling out of the intake end 230 and into the enclosure 202. The feed channel 208 is configured to receive feedstock material from the outlet 224 of the feed material reservoir 206 at the intake end 230, and guide the feedstock material towards the outlet end 232 and into the crucible 108 of the crystal growing system 100.

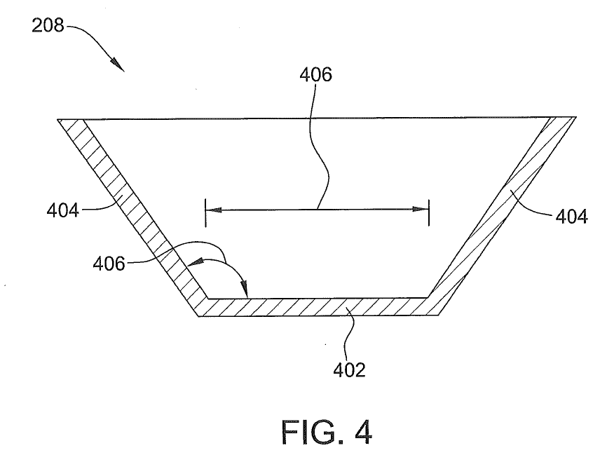

FIG. 4 is a cross-section of the feed channel 208 shown in FIGS. 1 and 3. As shown in FIG. 4, the feed channel 208 includes a base 402 and a pair of sidewalls 404 extending from opposite side edges of the base 402. In the embodiment illustrated in FIG. 4, each sidewall 404 extends from the base 402 at an oblique angle 406 thereto. The sidewalls 404 may extend from the base 402 at any suitable angle that enables the feed system 200 to function as described herein, such as between about 30° and about 90°. In some embodiments, the sidewalls 404 may be oriented substantially perpendicular to the base 402.

Components of the feed channel 208 may include an inert or non-reactive coating or cover to inhibit contamination of feedstock material. In some embodiments, for example, at least the interior surfaces of the sidewalls 404 and the base 402 of the feed channel 208 are covered with a quartz sleeve. In other embodiments, the sidewalls 404 and the base 402 of the feed channel 208 are coated with silicon.

The feed channel 208 is suitably sized and shaped to feed feedstock material from the feed material reservoir 206 through the opening 212 in the enclosure 202 and the housing feed port 126. In some embodiments, the feed channel 208 is configured to feed chunk poly-silicon having a maximum feature size or length of at least about 30 mm, more suitably, at least about 40 mm, yet even more suitably, at least about 45 mm, and even up to about 60 mm. In some embodiments, for example, a minimum width 406 of the feed channel 208 as measured between the sidewalls 404 is at least about 10 cm, more suitably at least about 12 cm, and yet even more suitably, at least about 15 cm.

Referring again to FIGS. 1-3, the feed channel 208 is configured to move between a first, retracted position (not shown), and a second, extended position (shown in FIGS. 1 and 3). When the feed channel 208 is in the extended position (shown in FIGS. 1 and 3), the feed channel 208 extends through the opening 212 in the enclosure 202 and the feed port 126 in the housing 102, and the outlet end 232 is positioned within the removal chamber 106. When the feed channel 208 is in the retracted position (not shown), the outlet end 232 of the feed channel 208 is recessed within the connector 214 of the feed system 200.

The feed system 200 may include any suitable device configured to move the feed channel 208 between the extended position and the retracted position. In the embodiment illustrated in FIGS. 1-3, the feed system 200 includes a linear slide mechanism 236 configured to move the feed channel 208 between the extended position and the retracted position along a generally horizontal direction, indicated by arrow 238 in FIG. 3. The feed system 200 is operably connected to a base plate 240 of the linear slide mechanism 236, which is supported by a plurality of roller bearings (not shown) that enable the base plate 240 to slide along the horizontal direction 238. The linear slide mechanism 236 may include one or more drive mechanisms (not shown) configured move the feed channel 208 and/or the base plate 240 in the horizontal direction 238. Suitable drive mechanisms include, but are not limited to, electric motors, pneumatic cylinders, servomechanisms, and combinations thereof.

In some embodiments, the feed system 200 includes a feed transport mechanism 244 configured to facilitate transporting feedstock material from the intake end 230 of the feed channel 208 towards the outlet end 232 of the feed channel 208. The feed transport mechanism 244 may include any suitable device or devices that enable the feed transport mechanism 244 to transport feedstock material from the intake end 230 of the feed channel 208 towards the outlet end 232. In some embodiments, for example, the feed transport mechanism 244 includes a mechanical oscillator configured to impart oscillatory motion to the feed channel 208 to facilitate the flow of granular or chunk feedstock material from the intake end 230 of the feed channel 208 towards the outlet end 232 of the feed channel 208.

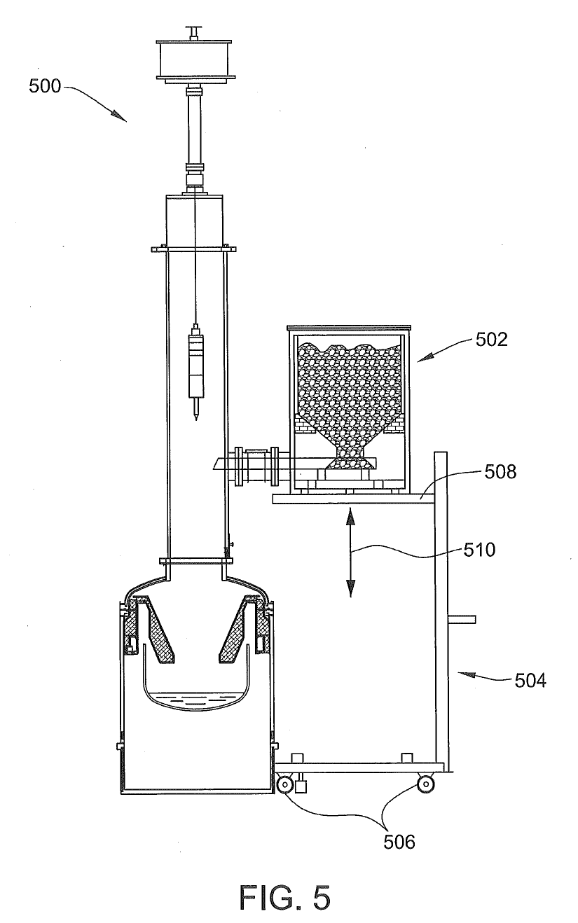

In some embodiments, the feed system 200 may be transportable such that the feed system 200 can be used to charge more than one crystal growing system 100 with feedstock material. In some embodiments, for example, the enclosure 202 is mounted on a moveable carriage (see, e.g., FIG. 5) that enables the feed system 200 to be transported to another crystal growing system (not shown) such that the feed system 200 can be used to charge multiple crystal growing systems with feedstock material.

In use, a desired amount of feedstock material is loaded into the feed material reservoir 206 through the inlet 222 of the feed material reservoir 206. The feedstock material is funneled downwardly by gravity through the outlet 224 and into the intake end 230 of the feed channel 208. In some embodiments, the feed system 200 is, loaded with relatively large chunk poly-silicon, such as chunk poly-silicon having a maximum feature size or length of at least about 30 mm, at least about 40 mm, at least about 45 mm, and even up to about 60 mm.

To charge a crucible with feedstock material, the enclosure connector 214 is connected to the housing connector. 128 to provide a sealed connection between the interior volume 204 of the enclosure 202 and the growth chamber 104 and the removal chamber 106. The feed channel 208 is moved in the horizontal direction 238 via the linear slide mechanism 236 from the retracted position (not shown) to the extended position (shown in FIGS. 1 and 3), such that, the outlet end 232 of the feed channel 208 is positioned within the removal chamber 106 of the housing 102. When the feed channel 208 is positioned in the extended position, feedstock material is fed along the feed channel 208 from the intake end 230 to the outlet end 232, and down through the removal chamber 106, through the opening 122 in the upper dome 118, and into the crucible 108. In embodiments including a guide tube 138 (FIG. 1), feedstock material is fed into the guide tube 138 from the outlet end 232 of the feed channel 208, and down through the guide tube 138 into the crucible 108. In some embodiments, a feed transport mechanism, such as a mechanical oscillator, is used to facilitate transporting feedstock material from the intake end 230 of the feed channel 208 towards the outlet end 232 of the feed channel 208. The feed system 200 may be used to provide an initial charge of feedstock material to a crucible, or to recharge a crucible following the growth of one or more crystal ingots.

In some embodiments, the feed system 200 is used to charge multiple crystal growing systems with feedstock material. In some embodiments, for example, after the crucible of a first crystal growing system is charged with feedstock material using the feed system 200, the feed system 200 is disconnected from the first crystal growing system, for example, by disconnecting the enclosure connector 214 of the feed system 200 from the housing connector 128. The feed system 200 is then transported to a second crystal growing system remote from the first crystal growing system, and connected to the second crystal growing system, for example, by connecting the enclosure connector 214 of the feed system 200 to a connector of the housing of the second crystal growing system. Feedstock material is then fed into a crucible of the second crystal growing system in the same manner as described above. Because the feed system 200 can be used to charge multiple crystal growing systems with feedstock material, the feed system 200 eliminates the need for every crystal growing system to have a dedicated feeding system, and thereby facilitates reducing the costs associated with growing single crystal ingots.

FIG. 5 is a cross-section of a crystal growing system 500 including another suitable embodiment of a feed system 502 mounted on a moveable carriage 504. The crystal growing system 500 and the feed system 502 may have substantially the same configuration as the crystal growing system 100 and the feed system 200 described above with reference to FIGS. 1-4, except the feed system 502 of FIG. 5 includes the moveable carriage 504.

The carriage 504 enables the feed system 502 to be transported to multiple crystal growing system (not shown) such that the feed system 502 can be used to charge multiple crystal growing systems with feedstock material. In particular, the carriage 504 includes a plurality of wheels 506 that enable the carriage 504 and the feed system 502 to be transported to another crystal growing system (not shown). The carriage 504 also includes an elevator platform 508 configured to move the feed system 502 up and down in a vertical direction, indicated by arrow 510 in FIG. 5, to facilitate connecting the feed system 502 to the removal chamber of the crystal growing system 500.

In some embodiments, the feed systems described herein are retrofitted onto commercial crystal growing systems to enable large chunk feedstock material, such as chunk poly-silicon, to be fed into the crystal growing systems. The feed systems described herein are particularly suited for retrofitting crystal growing systems without modifying the hot zone configuration of such systems. As used herein, the term “hot zone configuration” generally refers to the arrangement of components within the growth chamber of a crystal growing system including, but not limited to, the crucible, the heat shield, and the heating elements.

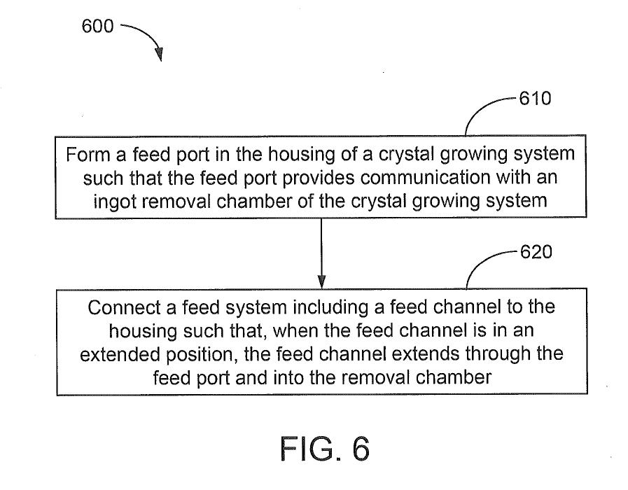

FIG. 6 is a flow chart of an example method 600 of retrofitting a crystal growing system with a feed system, such as the feed system 200 shown in FIGS. 1-3. The crystal growing system may have the same configuration as the crystal growing system 100 shown in FIG. 1, and include a housing defining a growth chamber and an ingot removal chamber positioned above the growth chamber. The method generally includes forming 610 a feed port in the housing such that the feed port provides communication with the removal chamber of the crystal growing system, and connecting 620 the feed system to the housing such that, when the feed channel is in an extended position, the feed channel extends through the feed port and into the removal chamber. In some embodiments, forming 610 a feed port in the housing includes forming a feed port having a diameter of at least about 150 mm, more suitably at least about 200 mm, and yet even more suitably, at least about 250 mm. In some embodiments, connecting 620 the feed system to the housing includes sealingly connecting the feed system to the housing. In some embodiments, the method 600 further includes connecting a connector to the housing, such as a vacuum flange, to facilitate sealingly connecting the feed system to the housing. In such embodiments, connecting 620 the feed system to the housing may include connecting the vacuum flange to a connector of the feed system.

The feed systems described herein are configured to increase the productivity of batch crystal growing systems by reducing the costs and downtime associated with batch crystal growing processes. For example, the feed systems described herein enable crystal growing systems to be recharged with feedstock material without cooling the system in between successive crystal growth cycles. The feed systems described herein thereby enable consumable components, such as quartz crucibles, to be re-used to grow multiple ingots, and reduce the down time associated with cooling crystal growing systems in between ingot growth cycles. Additionally, the feed systems described herein are configured to feed less expensive, large chunk poly-silicon into the crucibles of crystal growing systems, thereby facilitating reducing the costs associated with growing single crystal ingots.

The feed systems described herein further facilitate reducing the costs associated with growing single crystal ingots by, for example, eliminating the need to provide a feed system on every crystal growing system. Embodiments, of the feed systems described herein are transportable to different crystal growing systems, and are connectable to crystal growing systems to enable one feed system to provide feedstock material into more than one crystal growing system.

Additionally, the feed systems described herein enable commercial batch CZ crystal growing systems to be retrofitted with feed systems capable of recharging the crucibles of such systems without modifying the hot zone configuration of such systems. For example, the feed systems described herein are configured to feed or provide feedstock material through a feed port in the removal chamber of a crystal growing system. The feed systems do not require modification of the hot zone configuration of the crystal growing system. Further, the feed systems described herein can be used with different types of CZ crystal growing systems with little to no modification of the crystal growing systems.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions and methods without departing from the scope of the invention, it is intended that all matter contained in the above description and shown in the accompanying drawings shall be interpreted as illustrative and not in a limiting sense.

1. A system for growing a crystal ingot from a melt, the system comprising:
a housing defining a growth chamber and an ingot removal chamber positioned above the growth chamber; and
a feed system including:
an enclosure;
a feed material reservoir positioned within the enclosure; and
a feed channel including an intake end and an outlet end, the intake end configured to receive feed material from the feed material reservoir;
wherein the housing has an opening in communication with the removal chamber and a connector proximate the opening, and the enclosure has an opening and a connector configured to mate with the housing connector, the feed channel moveable between a retracted position and an extended position in which the feed channel extends through the opening in the housing and the outlet end is positioned within the removal chamber.

2. The system of claim 1 further comprising a carriage moveable between multiple crystal growing systems, wherein the feed system is mounted on the carriage such that the feed system is transportable to multiple crystal growing systems.

3. The system of claim 1 further comprising a heat shield positioned within the growth chamber, the heat shield defining an annular opening sized and shaped to receive a crystal ingot therethrough, wherein the feed system is configured to feed chunk feedstock material through the annular opening of the heat shield.

4. The system of claim 1, wherein the housing includes an upper dome defining an opening providing communication between the growth chamber and the removal chamber, wherein the feed system is configured to feed chunk feedstock material through the opening in the upper dome.

5. The system of claim 1, wherein the feed system is configured to feed chunk feedstock material having a maximum feature size greater than about 30 mm.

6. The system of claim 6, wherein the feed system is configured to feed chunk feedstock material having a maximum feature size of at least about 45 mm.

7. The system of claim 1, wherein the opening in the housing has a diameter of at least about 150 mm.

8. The system of claim 7, wherein the opening in the housing has a diameter of at least about 200 mm.

9. The system of claim 1, wherein the feed channel has a width of at least about 10 cm.

10. The system of claim 9, wherein the feed channel has a width of at least about 15 cm.

11. The system of claim 1, wherein the feed channel is mounted on a linear slide mechanism, the feed channel configured to slide along the linear slide mechanism between the retracted position and the extended position.

12. The system of claim 1, wherein the enclosure connector is operably connected to the enclosure by an expansion joint, the expansion joint configured to expand and retract to enable the enclosure connector to move relative to the enclosure.

13. A feed system for use with a crystal growing system including a housing defining a growth chamber and a removal chamber positioned above the growth chamber, the feed system comprising:
an enclosure defining an interior volume and an opening providing communication with the interior volume, the enclosure including a connector proximate the opening and configured to connect the enclosure to the housing;
a feed material reservoir positioned within the interior volume of the enclosure; and
a feed channel including an intake end and an outlet end, the intake end configured to receive feed material from the feed material reservoir, the feed channel moveable between a retracted position and an extended position in which the feed channel extends through the opening in the enclosure and into the removal chamber of the crystal growing system.

14. The system of claim 13 further comprising a moveable carriage, the enclosure mounted on the carriage such that the feed system is transportable to multiple crystal growing systems.

15-20. (canceled)

21. The system of claim 13, wherein the feed channel is mounted on a linear slide mechanism, the feed channel configured to slide along the linear slide mechanism between the retracted position and the extended position.

22. The system of claim 13, wherein the enclosure connector is operably connected to the enclosure by an expansion joint, the expansion joint configured to expand and retract to enable the enclosure connector to move relative to the enclosure.

23. A method of retrofitting a crystal growing system with a feed system including a feed channel moveable between a retracted position and an extended position, the crystal growing system including a housing defining a growth chamber and an ingot removal chamber positioned above the growth chamber, the method comprising:
forming a feed port in the housing, the feed port providing communication with the removal chamber of the crystal growing system; and
connecting the feed system to the housing such that, when the feed channel is in the extended position, the feed channel extends through the feed port and into the removal chamber.

24. The method of claim 23, wherein forming a feed port includes forming a feed port having a diameter of at least about 150 mm.

25. The method of claim 24, wherein forming a feed port includes forming a feed port having a diameter of at least about 200 mm.

26. The method of claim 23 further comprising connecting a vacuum flange to the housing proximate the feed port, wherein connecting the feed system to the housing includes connecting the vacuum flange to a connector of the feed system.
